(19) United States
(12) Patent Application Publication
(10) Pub. No.: US 2021/0360177 A1
(43) Pub. Date: Nov. 18, 2021

(54) GLOBAL SHUTTER TIME-OF-FLIGHT CAMERA

(71) Applicant: Microsoft Technology Licensing, LLC, Redmond, WA (US)

(72) Inventor: Minseok OH, San Jose, CA (US)

(73) Assignee: Microsoft Technology Licensing, LLC, Redmond, WA (US)

(21) Appl. No.: 15/930,055

(22) Filed: May 12, 2020

(51) Int. Cl. H04N 5/353; H04N 5/378; G01S 17/894; H04N 5/359; G01S 7/481

(52) U.S. Cl. CPC H04N 5/353; H04N 5/378; G01S 7/4816; H04N 5/3597; G01S 17/894

(57) ABSTRACT

Examples are disclosed herein relating to time-of-flight camera systems. One example provides a time-of-flight camera, comprising a global shutter image sensor comprising a plurality of pixels, each pixel of the plurality of pixels comprising a drain gate, and two or more taps, each tap comprising a storage diode configured to receive charge during an integration period, a floating diffusion capacitor configured to receive charge overflow from the storage diode during the integration period, and a dual conversion gate capacitor configured to receive charge overflow from the floating diffusion capacitor during the integration period.

### BACKGROUND

A time-of-flight (ToF) camera determines a depth of a subject relative to the ToF camera based on the known speed of light and a measured time of flight of light between the ToF camera and the subject. For example, a light signal may be temporally modulated to illuminate the subject. The back-reflected light signal may be acquired by a sensor array of the ToF camera and evaluated to determine a phase difference from which the depth may be calculated.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to time-of-flight camera systems. One example provides a time-of-flight camera comprising a global shutter image sensor comprising a plurality of pixels. Each pixel of the plurality of pixels comprises two or more taps, each tap comprising a storage diode configured to receive charge during an integration period, a floating diffusion capacitor configured to receive charge overflow from the storage diode during the integration period, and a dual conversion gate capacitor configured to receive charge overflow from the floating diffusion capacitor during the integration period.

### BRIEF DESCRIPTION OF THE DRAWINGS

FIG. 1 is an exploded, schematic view showing aspects of an example time-of-flight (ToF) camera.

FIG. 2 schematically shows a circuit diagram of an example ToF pixel.

FIG. 3 shows an example potential diagram for the ToF pixel of FIG. 2.

FIG. 4 schematically shows a cross sectional view of a portion of the ToF pixel of FIG. 2.

FIG. 5 schematically shows a circuit diagram of another example ToF pixel.

FIG. 6 shows an example potential diagram for the ToF pixel of FIG. 5.

FIG. 7 schematically shows a cross sectional view of a portion of the ToF pixel of FIG. 5.

FIG. 8 shows an example timing diagram for a global shutter ToF camera.

FIG. 9 shows an example timing diagram for a pixel of an example global shutter ToF camera.

FIG. 10 shows an example signal response plot illustrating the accumulation of charge corresponding to HCG and LCG signals of an example ToF pixel.

FIG. 11 shows a combination of HCG and LCG signals of the signal response plot of FIG. 10, and illustrates a dynamic range provided by the HCG and LCG signals.

FIGS. 12-14 illustrate examples of differential readouts from a ToF pixel for various combinations of differential exposure intensities across pixel taps.

FIG. 15 is a flow diagram showing an example method for determining a final differential output signal based on differential readout architecture.

FIG. 16 schematically shows a circuit diagram of yet another example ToF pixel.

FIG. 17 schematically shows an example cross-sectional view of the ToF pixel of FIG. 16.

FIG. 18 shows an example potential diagram for the global shutter ToF pixel of FIG. 17.

FIG. 19 shows an example method of operating a ToF camera.

FIG. 20 is a block diagram of an example computing system.

### DETAILED DESCRIPTION

A time-of-flight (ToF) camera may determine a depth of a subject (a distance from the subject to the camera) based on the phase difference of a light signal that is temporally modulated by a time-of-flight illuminator. A ToF sensor may be able to modulate the pixel response in synchronization with a modulated illumination source, and read out at least two signals per pixel, depending on a number of pixel taps. A global shutter mechanism may be used to simultaneously modulate the entire pixel array.

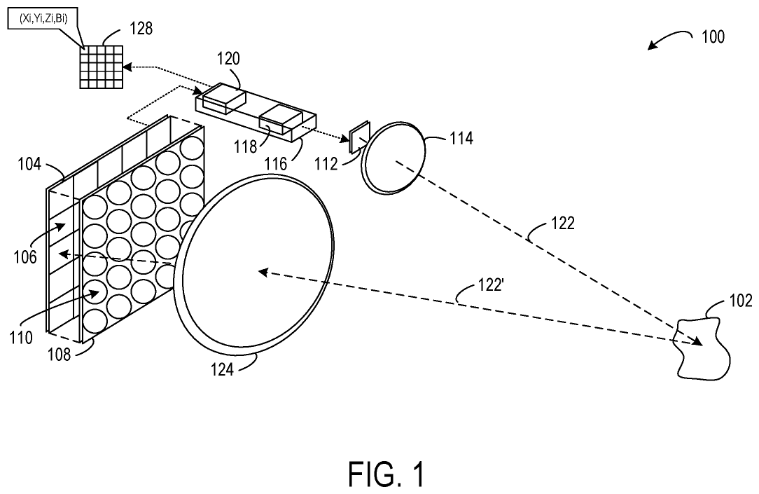

FIG. 1 shows aspects of an example ToF camera 100 configured to operate in such a manner. The term ‘camera’ refers herein to any imaging component having at least one optical aperture and sensor array configured to image a scene or subject 102. Camera 100 includes a sensor array 104 of individually addressable sensors 106, also referred to as pixels. Each sensor 106 may further include a plurality of pixel taps, or detection units that each detects samples. In some implementations, the sensors may be complementary metal-oxide semiconductor (CMOS) elements, but other suitable architectures are also envisaged. Each sensor may be responsive to light over a broad wavelength band, although this is not required. For silicon-based sensors, the wavelength response may range from 300 to 1100 nm, for example. Sensor array 104 is schematically illustrated with twenty-five sensors 106 for simplicity, although any suitable number of sensors 106 may be used.

Microlens array 108 optionally may be arranged directly over sensor array 104. Microlens array 108 includes a plurality of microlens elements 110. Each microlens element 110 of microlens array 108 may be registered to a sensor 106 of the sensor array 104. When included, microlens array 108 may provide a larger effective fill factor at each of the sensors, for increased collection efficiency and reduced cross-talk between pixels.

A ToF illuminator 112 is configured to emit active IR light to illuminate the subject 102. In one example, the ToF illuminator 112 includes an IR laser configured to emit IR light. In some examples, the ToF illuminator 112 optionally may include a diffuser 114 covering a field of illumination of the ToF illuminator 112. Depth measurements may be taken using IR light, including NIR light, or any other suitable wavelength. Although not shown in FIG. 1, the camera optionally may include a bandpass filter to limit the portion of the electromagnetic spectrum reaching the sensors 106 to the portion of the electromagnetic spectrum emitted by the ToF illuminator 112.

Electronic controller 116 may include a logic machine and associated storage machine. The storage machine may hold instructions that cause the logic machine to enact any operation, algorithm, computation, or transformation disclosed herein. In some implementations, the logic machine may take the form of an application-specific integrated circuit (ASIC) or system-on-a-chip (SoC), in which some or all of the instructions are hardware- or firmware-encoded. Electronic controller 116 includes a ToF controller machine 118 and an output machine 120 that may be operatively connected to the sensor array 104 and/or the ToF illuminator 112. Machines 118 and 120 may be implemented as separate physical hardware and/or firmware components or incorporated into a single hardware and/or firmware component.

The ToF controller machine 118 is configured to repeatedly activate the ToF illuminator 112 and synchronously address the sensors 106 of sensor array 104 to acquire IR images. The active light signal emitted from the ToF illuminator 116 may be temporally modulated in different modulation frequencies for different IR image captures. In the illustrated example, the ToF controller machine 118 activates the ToF illuminator 112 to illuminate the subject 102 with active IR light 122 and addresses the sensors 106 of sensor array 104 in synchronicity. IR light 122′ reflects from the subject 102 back to the camera 100. The reflected IR light 122′ passes through receiving optics 124 and is incident on the sensors 106 of the sensor array 104 to provide a measurement. For example, the measurement may be an intensity measurement of active IR light back-reflected from the subject to the sensor. In the illustrated example, IR light 122′ is measured by a sensor 106 of sensor array 104, thus providing phase information useable with the knowledge of the camera's configuration to determine the world space position of a locus of subject 102.

The ToF controller machine 118 is configured to generate a depth image 128 based on a plurality of captured IR images. The term ‘depth image’ refers to an array of image pixels registered to corresponding regions (Xᵢ, Yᵢ) of an imaged scene, with a depth value Zᵢ indicating, for each image pixel, the depth of the corresponding region. ‘Depth’ is defined as a coordinate parallel to the optical axis of the camera, which increases with increasing distance from the camera. The term ‘depth video’ refers herein to a time-resolved sequence of depth images. The output machine 120 is configured to output the depth image 128 generated by the ToF controller machine 118. The output machine 120 may be configured to output the depth image 128 in any suitable form. In some examples, the output machine 120 may output the depth image 128 as a data structure in which each element of the matrix corresponds to a different pixel.

High dynamic range along with acceptable signal-to-noise ratio at a wide temperature range may be desired for some ToF cameras. High speed operation with extended effective full-well capacity may be achieved by programming the duty cycle of photoelectron integration. However, such a solution may provide the disadvantage of a high noise floor. Lateral overflow along with a split photodiode also may be used. For example, using a high conversion gain with a large photodiode and lateral overflow with a small photodiode, a relatively lower noise floor and higher effective full-well capacity may be achieved. However, due to the high gain ratio between large and small photodiodes caused by optical gain and conversion gain ratio, dark signal non-uniformity of small photodiodes may be amplified, and may be visible at high temperatures.

Accordingly, examples are disclosed that relate to a ToF image sensor that is integrated via a global shutter and provides relatively higher dynamic range, lower noise floor, higher full-well capacity, and lower power consumption than current ToF sensors. The disclosed examples are further suitable for small pixel pitch, such as 2-3 μm, as an example range. A low noise floor extends the maximum distance of each ToF pixel, and a higher full-well capacity enables a shorter minimum distance of each ToF pixel and more reliable operation under ambient light compared to current ToF sensors.

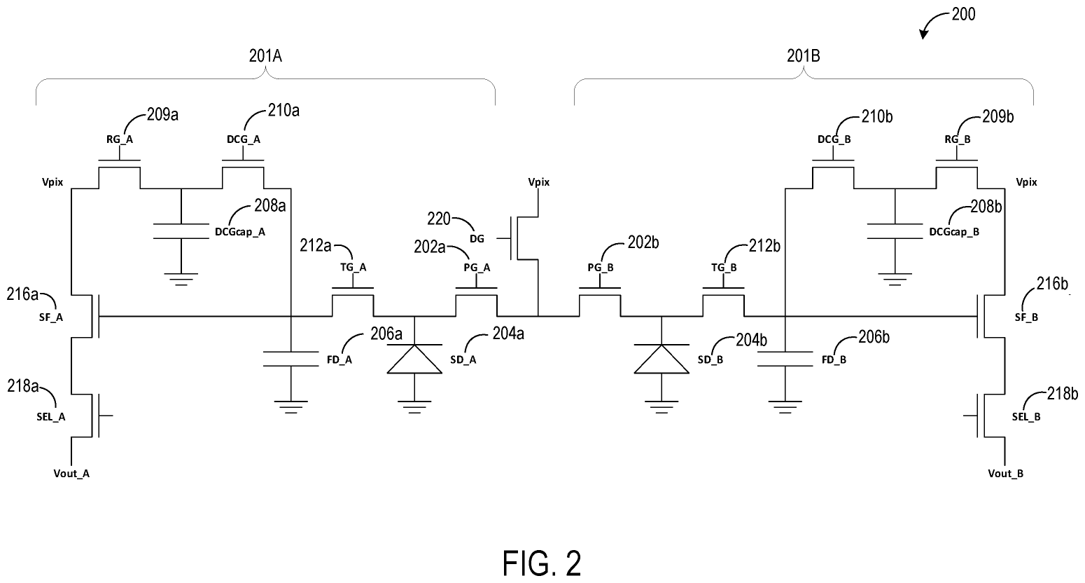

FIG. 2 schematically shows an example global shutter ToF pixel 200 for a ToF camera in accordance with the present disclosure. ToF pixel 200 includes two taps, indicated here as tap 201A and tap 201B via A and B labels on the illustrated components. In other examples, a ToF pixel may include any other suitable number of taps. Each pixel tap includes a photogate 202a, 202b configured to accumulate charge during an integration period. In other examples, photodiodes may be used instead of photogates. During an integration period, photogates PG_A 202a and PG_B 202b are modulated out of phase from each other, as described in more detail below.

Each pixel tap also includes a storage diode 204a, 204b configured to receive and store charge that is accumulated at the corresponding photogate 202a, 202b during the integration period. The storage diodes 204a, 204b (SD_A and SD_B) may comprise pinned diodes, as an example. The use of storage diodes as opposed to storage gates may provide various advantages. For example, while a storage gate offers wider voltage swing, the oxide interface of the storage gate also may contribute significant dark current, and thereby increase the noise floor. In contrast, a pinned diode may contribute less dark current, and thereby extend a dynamic range of the pixel tap on a lower signal end. Further, the use of a pinned diode does not require pulsing, as with a storage gate, and thus may reduce power consumption compared to the use of a storage gate.

Once each storage diode 204a, 204b is fully filled with charge, a floating diffusion (FD) capacitor 206a, 206b for each pixel tap (FD_A and FD_B) is configured to receive charge overflow from the storage diode 204a, 204b. Further, when FD capacitor 206a, 206b fills, a dual conversion gate (DCG) capacitor 208a, 208b receives charge overflow from the FD capacitor 206, thereby extending the full-well capacity and dynamic range of each pixel tap on a higher signal end. DCG capacitor 208a, 208b may be any suitable type of capacitor (e.g. metal oxide semiconductor, metal-oxide-metal, or metal-insulator-metal) and may be implemented as a back end of line (BEOL) structure to save pixel area.

During a readout period, a controller may be configured to read a first voltage arising from a first portion of charge that includes charge stored on the FD capacitor 206a, 206b and charge stored on the DCG capacitor 208a, 208b. The controller further may be configured to read a second voltage arising from a second portion of charge that is stored on the storage diode 204a, 204b. First, for each pixel tap, the controller measures the first voltage by opening a DCG transistor 210a, 210b between the DCG capacitor 208a, 208b and the FD capacitor 206a, 206b to connect the DCG capacitor 208a, 208b and the FD capacitor 206a, 206b in parallel, and then reads the first voltage. The resulting signal also may be referred to herein as a low conversion gain (LCG) signal. Next, the controller drains the first portion of charge via a reset gate 209a, 209b. After draining the first portion of charge, the controller closes the DCG transistor 210a, 210b, and then opens a transfer gate 212a, 212b to transfer the second portion of charge from the storage diode 204a, 204b to the FD capacitor 206a, 206b. The controller then reads the second voltage. This signal also may be referred to herein as a high conversion gain (HCG) signal, as the use of the FD capacitor alone for the readout provides higher gain than the parallel combination of the FD capacitor and DCG capacitor.

The ToF pixel 200 further includes for each tap, a source follower 216a, 216b across which the output voltage is measured, and a selection gate 218a, 218b operable to select a tap for readout. The pixel further includes a drain gate 220 that is held low during integration, and high during readout. In other examples, a drain gate 220 may be omitted.

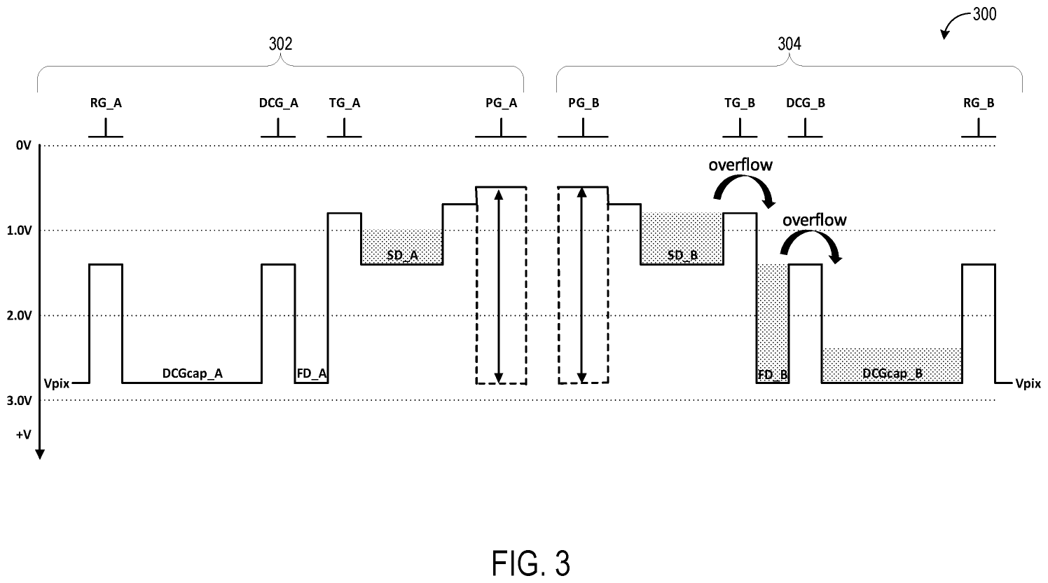

FIG. 3 shows an example potential diagram 300 for the global shutter ToF pixel of FIG. 2. The drain gate is omitted here for simplicity. A first tap 302 illustrates a lower intensity signal on a lower end of a dynamic range of the pixel, and a second tap 304 illustrates a higher intensity signal on a higher end of a dynamic range. As shown on second tap 304, overflow occurs from the storage diode to the FD capacitor and then to the DCG capacitor, extending the full-well capacity of the pixel tap compared to a tap that omits the DCG capacitor. In some examples, the storage capacity of the storage diode may be selected based upon the floating diffusion capacitance (e.g. to match the floating diffusion capacitance). As an example, a ratio of HCG (FD capacitor):LCG (FD+DCG capacitor) capacitances may be 10-20, in order to extend single-exposure dynamic range by 20-40 dB. This may allow the use of a relatively small storage diode. This may result in a relatively low pixel fill-factor, which may provide the benefits of both shutter efficiency and flexibility of the pixel area. In other examples, the storage diode may have any other suitable storage capacity.

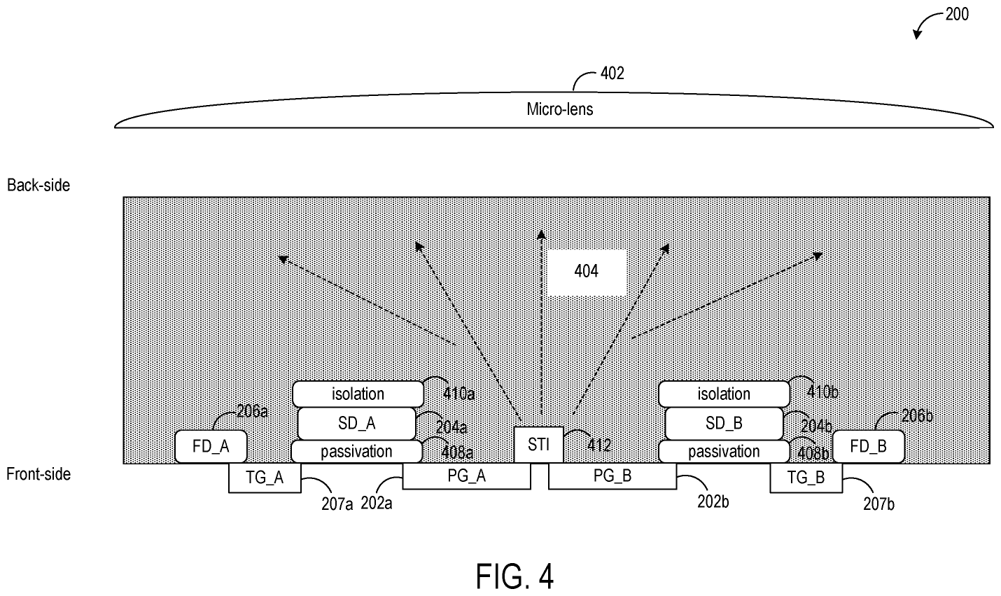

FIG. 4 schematically shows a cross-sectional view of a portion of the pixel 200. Light incident on pixel 200 is focused by a micro-lens 402 onto the pixel area, and generates photoelectrons within a bulk area 404 (e.g. an epitaxial silicon region) of the pixel 200. The photoelectrons are directed by an electric field (represented by arrows in bulk area 404) toward one of photogates PG_A 202a or PG_B 202b, depending upon which tap is being integrated. Electrons accumulated at photogates PG_A and PG_B are respectively transferred to storage diodes SD_A 204a and SD_B 204b.

The depicted storage diodes 204a, 204b are bordered by a passivation layer 408a, 408b formed at a first side to help reduce dark current, and by an isolation layer 410a, 410b on a second side. In some examples, the passivation layers 408a, 408b and the isolation layers 410a, 410b may be formed via p-type doping, and the storage diodes 204a, 204b may be formed via n-type doping. In other examples, the passivation layers 40a, 408b and the isolation layers 410a, 410b may be formed in any other suitable manner.

ToF pixel 200 further includes an integrated shallow trench isolation (STI) region 412, which redistributes incident light inside the pixel area, and acts as physical barrier to the movement of electrons between different components of the ToF pixel 200, preventing electric current leakage and thereby helping to improve modulation contrast compared to pixels that omit an STI. The resulting lower current leakage may help to prevent the storage diodes 204a, 204b from accumulating charge arising from noise, and thereby help to preserve modulation contrast.

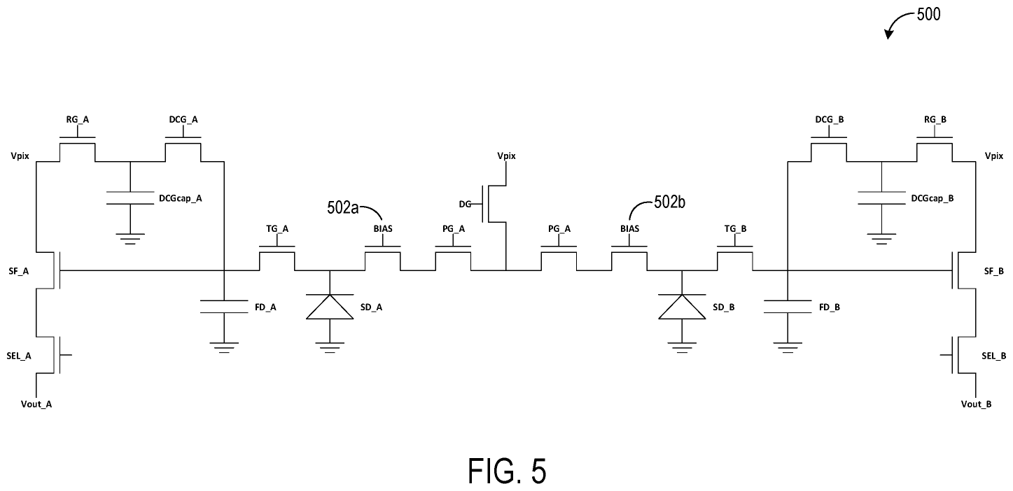

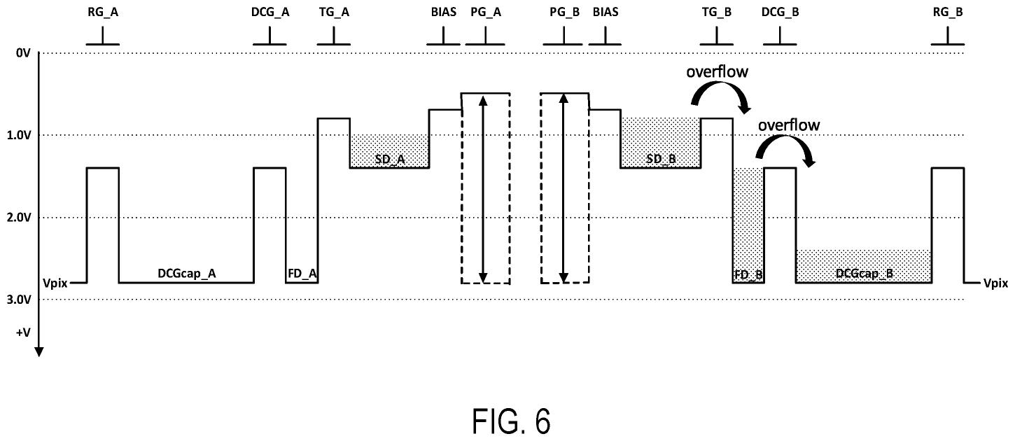

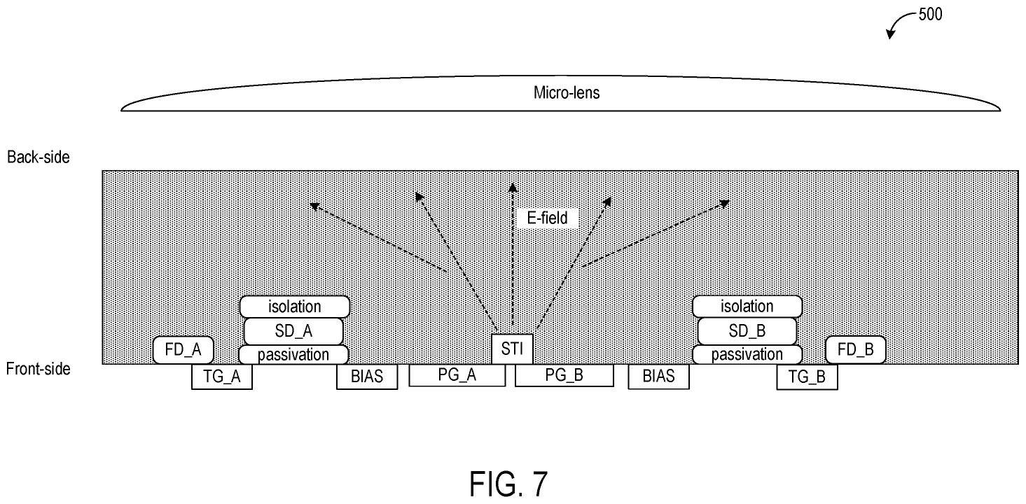

FIG. 5 schematically shows another example global shutter ToF pixel 500, which has a similar configuration to that of FIG. 2, but that includes bias gates 502a, 502b in between the photogates and the storage diodes. The bias gates 502a, 502b may facilitate pixel operation using various bias voltage options, for example, to provide further control of a potential barrier between the photogate and storage diode. FIG. 6 shows an example potential diagram for the global shutter ToF pixel 500, illustrating a potential barrier provided by the bias gates, and FIG. 7 schematically shows a cross-section of the example global shutter ToF pixel 500.

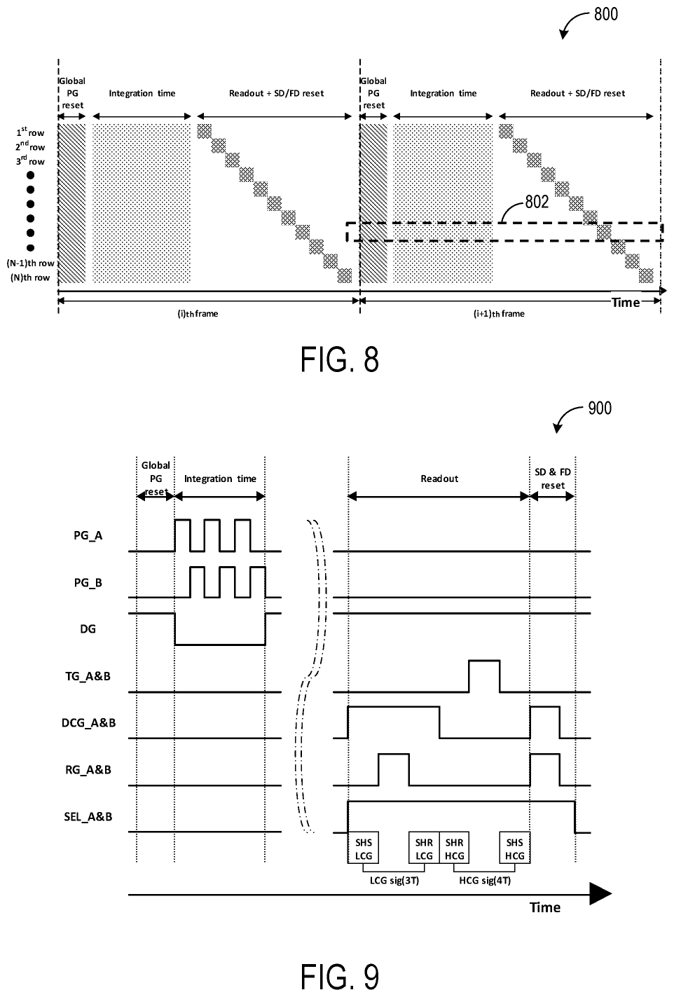

FIG. 8 shows an example timing diagram 800 for a global shutter ToF image sensor comprising N rows of pixels. The timing diagram 800 shows two arbitrary image frames, illustrated as the (i)^{th} frame and the (i+1)^{th} frame. Each frame includes a global reset period, an integration period in which light exposure is integrated by the pixel taps, and then a readout and reset period.

As mentioned above, the readout includes both an LCG signal readout and an HCG signal readout. The LCG signal includes uncorrelated double sampling (3T-read) of overflow electrons in the FD capacitor and DCG capacitor, and the HCG signal includes correlated double sampling (4T-read) of electrons stored in the storage diode. The LCG signal and HCG signal are combined in the digital domain. In other examples, they may be combined in the analog domain.

FIG. 9 shows a detailed view of a more detailed timing diagram 900, illustrating the operation of a pixel (or row of pixels) of the diagram of FIG. 8. While illustrated as representing window 802 of FIG. 8, the timing shown in FIG. 9 can be followed by all rows of pixels with appropriate relative timing compared to other rows.

As shown, PG_A and PG_B are modulated out of phase from each other, synchronized with the light source. When light returns to the sensor, a phase difference may exist between the synchronized signal and the returning light signal. By measuring the amplitude of the signal, the phase difference can be calculated.

During integration time, the drain gate (DG) is off. During readout, charge from the FD capacitor and the DCG capacitor are combined for readout as a first portion of charge by opening the DCG transistors (DCG_A and DCG_B) to obtain am LCG signal. The DCG transistors are then closed, after which transfer gates (TG_A and TG_B) are opened to transfer charge from the storage diodes to the FD capacitors, which is read out as a second portion of charge to obtain an HCG signal. After reading the charges, the reset gates (RG_A and RG_B) are opened, to reset the storage diodes and the FD capacitors, before moving on to the next integration.

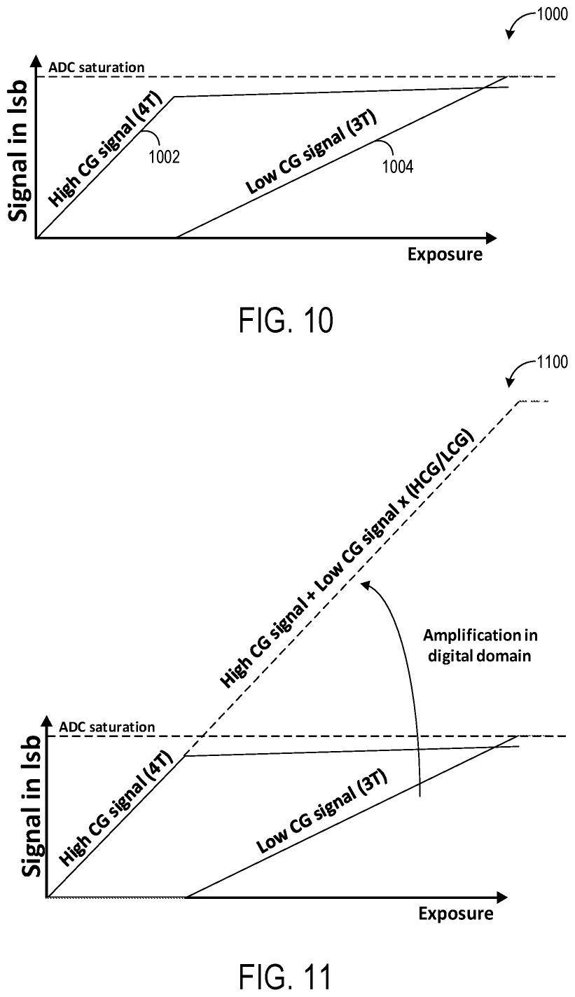

FIG. 10 shows an example signal response plot 1000 for a ToF pixel as disclosed herein. The HCG signal 1002 is based on charge accumulated on the storage diode during integration and is read using correlated double sampling (4T-readout). The LCG signal 1004 is based on overflow charge accumulated the signal from both the FD capacitor and the DCG capacitor. The HCG signal 1002 may provide higher responsivity, a lower noise floor, and a smaller full-well capacity, and thus help to provide suitable performance at a lower end of a dynamic range (e.g. low light exposure). The LCG signal 1004 may provide lower responsivity, a higher noise floor, and a larger full-well capacity, allowing for suitable performance at a higher end of a dynamic range (e.g. high light exposure). FIG. 11 shows a graph 1100 illustrating the effective increase in dynamic range offered by the combination of the HCG and LCG signals—while each signal remains below a saturation of an analog/digital converter, the combined signal allows a higher signal to be detected. Due to the combination of HCG and LCG signals, the LCG signal is amplified by conversion gain or capacitance ratio between HCG and LCG in the digital domain (or analog domain where suitable). As such, full-well capacity is extended while avoiding pixel performance degradation.

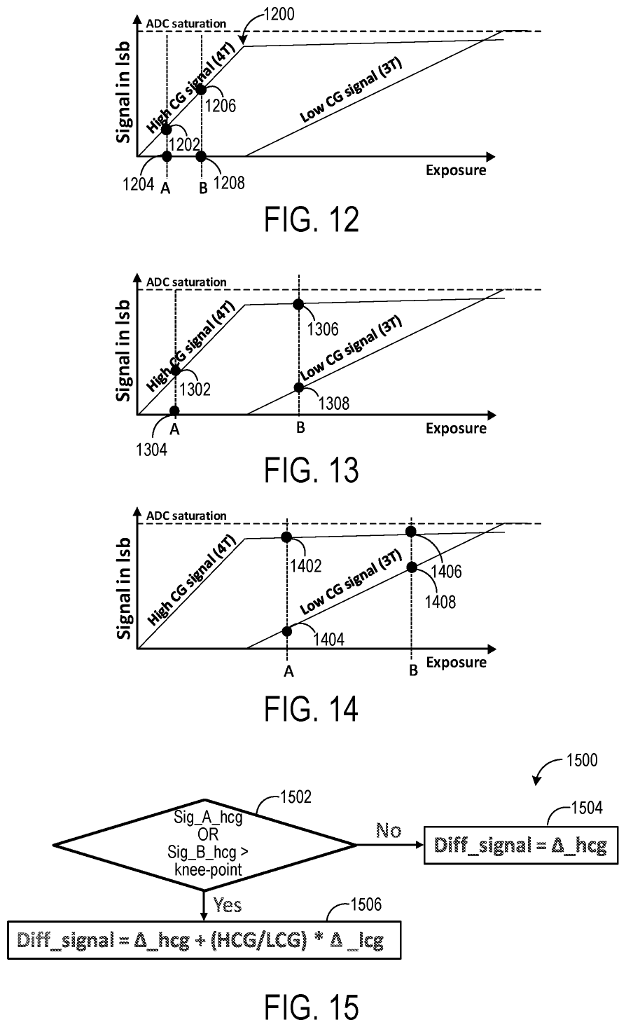

In some examples, a ToF image sensor may provide a differential signal between an output. Thus, FIGS. 12-15 illustrate a process for combining signals from a ToF pixel that utilizes a differential readout. First, FIG. 12-14 illustrate three different possible relationships between the signals from the taps. FIG. 12 shows a case where the signals from tap A and tap B are both below the maximum storage capacity of the storage diode (referred to as the knee-point 1200). In FIG. 12, the HCG signal from tap A is shown at 1202, the LCG signal from tap A is shown at 1204, the HCG signal from tap B is shown at 1206, and the LCG signal from tap B is shown at 1208. FIG. 13 shows a case where the signal from tap A is less than the knee-point and the signal from tap B is greater than the knee-point. In FIG. 13, the HCG signal from tap A is shown at 1302, the LCG signal from tap A is shown at 1304, the HCG signal from tap B is shown at 1306, and the LCG signal from tap B is shown at 1308. FIG. 14 shows a case where the signals for both taps A and B are greater than the knee-points. In FIG. 14, the HCG signal from tap A is shown at 1402, the LCG signal from tap A is shown at 1404, the HCG signal from tap B is shown at 1406, and the LCG signal from tap B is shown at 1408. Additional information available regarding light intensity may be used to help determine if the signals from tap A and tap B are less than or greater than the knee-point, such as information from additional circuitry monitoring the V_out signal for each tap (e.g. based on a threshold for V_out_A minus V_out_B).

For FIG. 12, a differential for the HCG signal (Δ_hcg) and for the LCG signal (Δ_lcg) are determined as follows.

Sig_A_hcg−Sig_B_hcg=Δ_hcg

Sig_A_lcg−Sig_B_lcg=Δ_lcg≈0

Diff_signal=Δ_hcg

For FIG. 13, the differential signals for the HCG and LCG signals are determined as follows:

Sig_A_hcg−Sig_B_hcg=Δ_hcg

Sig_A_lcg−Sig_B_lcg=Δ_lcg

Diff_signal=Δ_hcg+(HCG/LCG)*Δ_lcg

For FIG. 14, the differential signals for the HCG signals and the LCG signals are determined as follows:

Sig_A_hcg−Sig_B_hcg=Δ_hcg

Sig_A_lcg−Sig_B_lcg=Δ_lcg

Diff_signal=Δ_hcg+(HCG/LCG)*Δ_lcg

FIG. 15 shows a flow diagram depicting an example method 1500 for determining a final differential output signal based on differential readout architecture. Method 1500 comprises, at 1502, determining whether Sig_A_hcg OR Sig_B_hcg is greater than the knee-point. If not, then at 1504, Diff_signal may be determined to equal Δ_hcg. If so, then at 1506, Diff_signal may be determined as Δ_hcg+(HCG/LCG)*Δ_lcg.

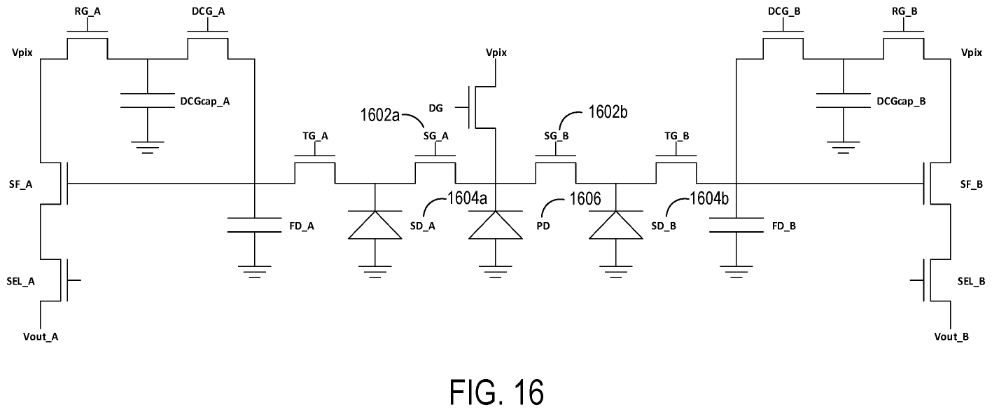

FIG. 16 schematically shows an electrical schematic diagram for another example ToF pixel. In this example, the pixel taps include a storage gate 1602a, 1602b in addition to the storage diode 1604a, 1604b. Further, a photodiode 1606 is introduced in between the two pixel taps. The photodiode pinning potential may be low but still provide sufficient built-in electric filed for demodulation contrast performance at high frequency. For example, electron mobility in silicon at 300K is approximately 1000 cm\hat{ }2/V/s. For example, electron drifts 10 um within 1 ns based on an E-field of 0.1 V/um(=0.6V/6 um). Due to a low photodiode pinning potential, the storage gates 1602a, 1602b may not require a relatively high booster voltage for demodulation, which leads to lower power consumption.

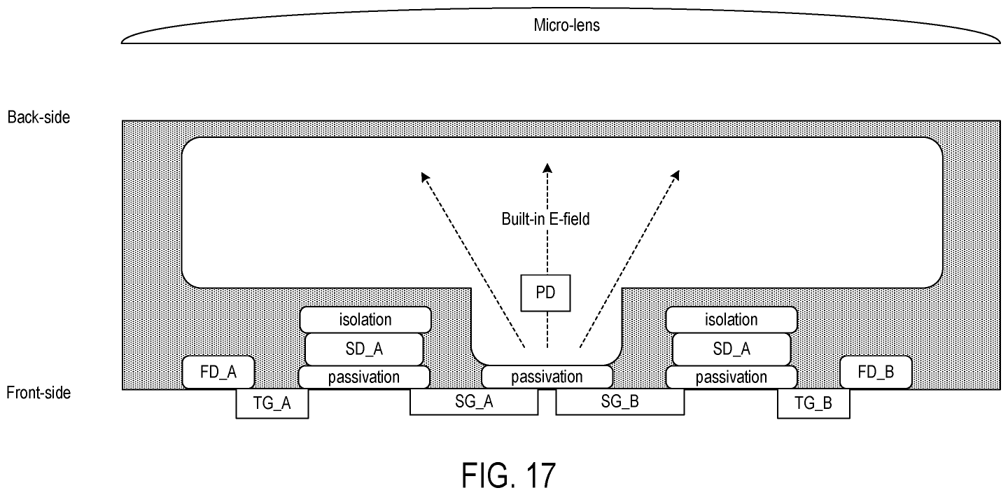

FIG. 17 schematically shows a cross-section of the global shutter ToF pixel of FIG. 16. Both PD and storage diodes are pinned and have passivation implants at the surface to minimize dark current. Generated photo-electrons are pulled toward either the storage gate by the built-in electric-filed, formed by fully depleted PD, and then are stored in a corresponding storage diode (SD_A or SD_B). PD area at the front-side may be small to provide for a higher demodulation contrast, and also leaves more of the pixel area for other pixel elements. The area of the storage diodes may be relatively low capacitance to ensure low power consumption.

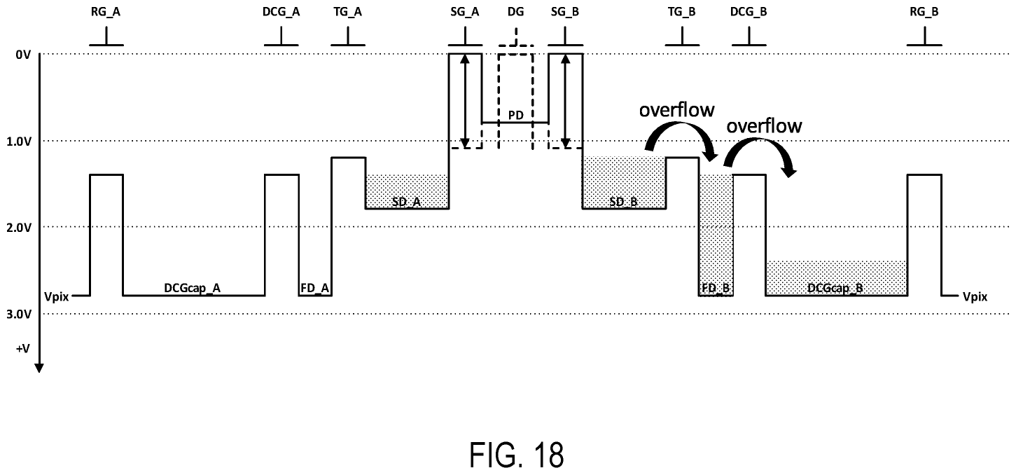

FIG. 18 shows an example potential diagram for the global shutter ToF pixel of FIG. 17, and illustrates overflow charge on tap B, compared to no overflow charge on tap A. This again illustrates the dynamic range provided by the use of a relatively low-noise storage diode and the DCG capacitor for each tap.

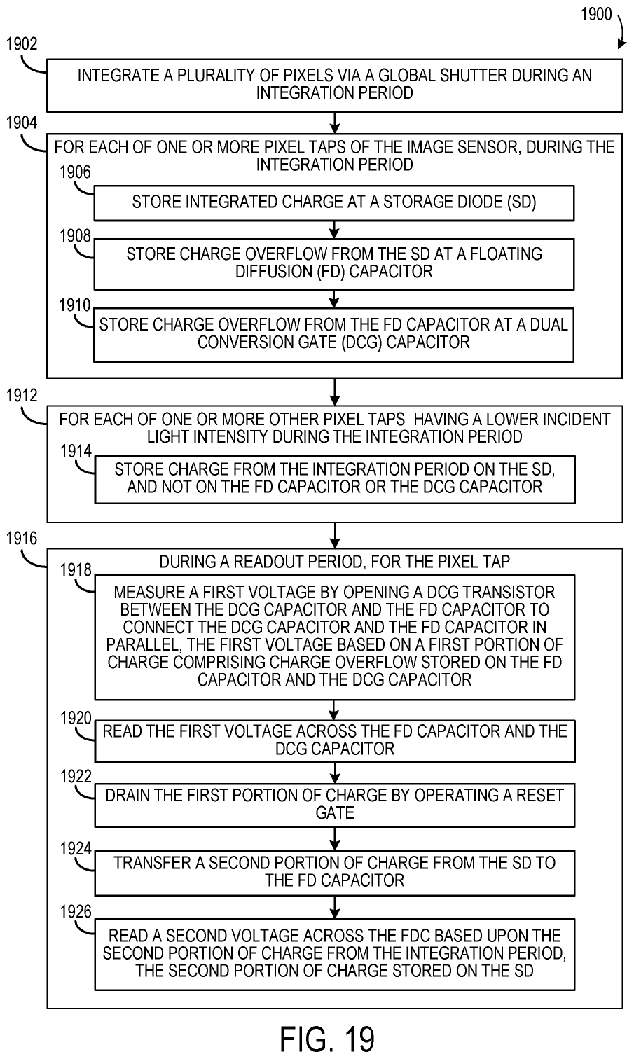

FIG. 19 shows a flow diagram depicting an example method of operating a ToF camera. Method 1900 includes, at 1902, integrating a plurality of pixels via a global shutter during an integration period. Method 1900 further includes, at 1904, for each of one or more pixel taps of the image sensor, during the integration period, at 1906, storing integrated charge at a storage diode. Where light intensity results in filling the storage diode with charge, then method 1900 includes storing charge overflow from the storage diode at a FD capacitor, at 1908. Additionally, where light intensity results in filling the floating diffusion capacitor with charge, method 1900 comprises, at 1910, storing charge overflow from the FD capacitor at a DCG capacitor. As described above, lateral overflow of charge from the storage diode to the FD capacitor and DCG capacitor in turn extends the full-well capacity of a pixel tap.

In some instances, some taps at a lower end of the dynamic range of the camera may not have the storage diode filled during integration. As such, the pixel taps integrated at 1904 may be a first set of pixel taps having a higher incident light intensity, and a second set of taps may have a lower incident light intensity. Method 1900 thus includes, for each of one or more other pixel taps having a lower incident light intensity during the integration period, storing charge the integration period on the storage diode, but not on the FD capacitor and the DCG capacitor, as shown at 1914.

Method 200 further includes, at 1916, during a readout period, for the pixel tap of each of the one or more pixel taps, at 1918, measuring a first voltage by opening a DCG transistor between the DCG capacitor and the FD capacitor to connect the DCG capacitor and the FD capacitor in parallel. The first voltage is the voltage arising from a first portion of charge comprising charge overflow stored on the FD capacitor and the DCG capacitor. Method 1900 next includes, at 1920, reading the first voltage across the FD capacitor and the DCG capacitor, after which, at 1922, the first portion of charge is drained by operating a reset gate. Method 200 then includes, at 1924, transferring a second portion of charge from the storage diode to the FD capacitor, and at 1926, reading a second voltage across the FD capacitor, which is the voltage arising from the second portion of charge stored on the storage diode.

In some embodiments, the methods and processes described herein may be tied to a computing system of one or more computing devices. In particular, such methods and processes may be implemented as a computer-application program or service, an application-programming interface (API), a library, and/or other computer-program product.

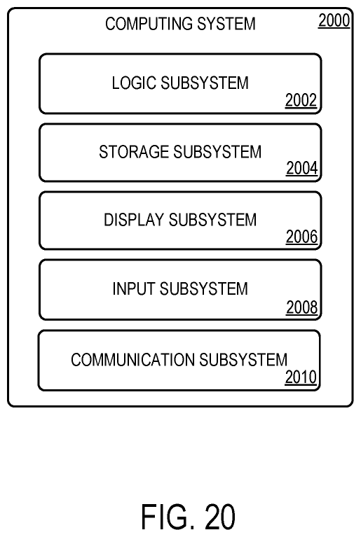

FIG. 20 schematically shows a non-limiting embodiment of a computing system 2000 that can enact one or more of the methods and processes described above. Computing system 2000 is shown in simplified form. Computing system 2000 may take the form of time-of-flight cameras, one or more personal computers, server computers, tablet computers, home-entertainment computers, network computing devices, gaming devices, mobile computing devices, mobile communication devices (e.g., smart phone), and/or other computing devices.

Computing system 2000 includes a logic subsystem 2002 and a storage subsystem 2004. Computing system 2000 may optionally include a display subsystem 2006, input subsystem 2008, communication subsystem 2010, and/or other components not shown in FIG. 20.

Logic subsystem 2002 includes one or more physical devices configured to execute instructions. For example, the logic subsystem 2002 may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic subsystem 2002 may include one or more processors configured to execute software instructions. Additionally or alternatively, the logic subsystem 2002 may include one or more hardware or firmware logic machines configured to execute hardware or firmware instructions. Processors of the logic subsystem 2002 may be single-core or multi-core, and the instructions executed thereon may be configured for sequential, parallel, and/or distributed processing. Individual components of the logic subsystem 2002 optionally may be distributed among two or more separate devices, which may be remotely located and/or configured for coordinated processing. Aspects of the logic subsystem 2002 may be virtualized and executed by remotely accessible, networked computing devices configured in a cloud-computing configuration.

Storage subsystem 2004 includes one or more physical devices configured to hold instructions executable by the logic subsystem 2002 to implement the methods and processes described herein. When such methods and processes are implemented, the state of storage subsystem 2004 may be transformed—e.g., to hold different data.

Storage subsystem 2004 may include removable and/or built-in devices. Storage subsystem 2004 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 2004 may include volatile, nonvolatile, dynamic, static, read/write, read-only, random-access, sequential-access, location-addressable, file-addressable, and/or content-addressable devices.

It will be appreciated that storage subsystem 2004 includes one or more physical devices. However, aspects of the instructions described herein alternatively may be propagated by a communication medium (e.g., an electromagnetic signal, an optical signal, etc.) that is not held by a physical device for a finite duration.

Aspects of logic subsystem 2002 and storage subsystem 2004 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 2006 may be used to present a visual representation of data held by storage subsystem 2004. This visual representation may take the form of a graphical user interface (GUI). As the herein described methods and processes change the data held by the storage machine, and thus transform the state of the storage machine, the state of display subsystem 2006 may likewise be transformed to visually represent changes in the underlying data. Display subsystem 2006 may include one or more display devices utilizing virtually any type of technology. Such display devices may be combined with logic subsystem 2002 and/or storage subsystem 2004 in a shared enclosure, or such display devices may be peripheral display devices.

When included, input subsystem 2008 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 2010 may be configured to communicatively couple computing system 2000 with one or more other computing devices. Communication subsystem 2010 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 2000 to send and/or receive messages to and/or from other devices via a network such as the Internet.

Another example provides a time-of-flight camera, comprising a global shutter image sensor comprising a plurality of pixels, each pixel of the plurality of pixels comprising a drain gate, and two or more taps, each tap comprising a storage diode configured to receive charge during an integration period, a floating diffusion capacitor configured to receive charge overflow from the storage diode during the integration period, and a dual conversion gate capacitor configured to receive charge overflow from the floating diffusion capacitor during the integration period. The time-of-flight camera may additionally or alternatively include a controller comprising instructions executable to control a pixel readout process in which the controller reads a first voltage based upon charge stored on the floating diffusion capacitor and charge stored on the dual conversion gate capacitor, and reads a second voltage based upon charge stored on the storage diode. The instructions may additionally or alternatively be executable to measure the first voltage by operating a dual conversion gate transistor between the dual conversion gate capacitor and the floating diffusion capacitor, and then read the first voltage. The instructions may additionally or alternatively be executable to operating a reset gate transistor to drain the charge stored on the floating diffusion capacitor and charge stored on the dual conversion gate capacitor before reading the second voltage. The instructions may additionally or alternatively be executable to control a transfer gate transistor to transfer charge to the floating diffusion capacitor to read the second voltage. The pixel may additionally or alternatively include one or more of a photodiode and a photogate. The storage diode may additionally or alternatively include a pinned diode. The time-of-flight camera may additionally or alternatively include a passivation layer between the storage diode and a front side of the image sensor. The time-of-flight camera may additionally or alternatively include an isolation layer between the storage diode and a bulk semiconductor portion of the image sensor.

Another example provides a time-of-flight camera, comprising a global shutter image sensor comprising a plurality of pixels, each pixel of the plurality of pixels comprising a drain gate, and two or more taps, each tap comprising a photogate, a storage diode configured to receive charge from the photogate during the integration period, a floating diffusion capacitor configured to receive charge overflow from the storage diode during the integration period, and a dual conversion gate capacitor configured to receive charge overflow from the floating diffusion capacitor during the integration period, and a controller comprising instructions executable to control each pixel during the integration period and also during a readout period in which the controller reads a first voltage based upon charge stored on the floating diffusion capacitor and charge stored on the dual conversion gate capacitor, and reads a second voltage based upon charge stored on the storage diode. The storage diode may additionally or alternatively include a pinned diode. The instructions may additionally or alternatively be executable to measure the first voltage by operating a dual conversion gate transistor between the dual conversion gate capacitor and the floating diffusion capacitor, and then reading the first voltage. The instructions may additionally or alternatively be executable to operating a reset gate transistor to drain the charge stored on the floating diffusion capacitor and charge stored on the dual conversion gate capacitor before reading the second voltage. The instructions may additionally or alternatively be executable to control a transfer gate transistor to transfer charge to the floating diffusion capacitor to read the second voltage. The time-of-flight camera may additionally or alternatively include a passivation layer between the storage diode and a front side of the image sensor. The time-of-flight camera may additionally or alternatively include an isolation layer between the storage diode and a bulk semiconductor portion of the image sensor.

Another example provides a method of operating a time of flight image camera comprising an image sensor, the method comprising integrating a plurality of pixels via a global shutter during an integration period, for each of one or more pixel taps of the image sensor, during the integration period, storing integrated charge at a storage diode, the storage diode comprising a pinned diode, storing charge overflow from the storage diode at a floating diffusion capacitor, and storing charge overflow from the floating diffusion capacitor at a dual conversion gate capacitor, during a readout period, for the pixel tap, reading a first voltage across the floating diffusion capacitor and the dual conversion gate capacitor, the first voltage based on a first portion of charge from the integration period, the first portion of charge comprising charge overflow stored on the floating diffusion capacitor and the dual conversion gate capacitor, draining the first portion of charge via a reset gate transistor, and reading a second voltage across the floating diffusion capacitor based upon a second portion of charge from the integration period, the second portion of charge stored on the storage diode. The one or more pixel taps may additionally or alternatively include a first set of pixels having a higher incident light intensity during the integration period, and the method further comprising, for each pixel tap of one or more pixels taps of a second set of pixel taps having a lower incident light intensity during the integration period, storing charge from the integration period on the storage diode and not on the floating diffusion capacitor or the dual conversion gate capacitor. The method may additionally or alternatively include measuring the first voltage by opening a dual conversion gate transistor between the dual conversion gate capacitor and the floating diffusion capacitor to connect the dual conversion gate capacitor and the floating diffusion capacitor in parallel, and then reading the first voltage. The method may additionally or alternatively include, after draining the first portion of charge, reading the second voltage by closing the dual conversion gate transistor, and then opening a transfer gate to transfer charge from the storage diode to the floating diffusion capacitor.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A time-of-flight camera, comprising
a global shutter image sensor comprising a plurality of pixels, each pixel of the plurality of pixels comprising
a drain gate, and
two or more taps, each tap comprising
a storage diode configured to receive charge during an integration period,
a floating diffusion capacitor configured to receive charge overflow from the storage diode during the integration period, and
a dual conversion gate capacitor configured to receive charge overflow from the floating diffusion capacitor during the integration period.

2. The time-of-flight camera of claim 1, further comprising a controller comprising instructions executable to control a pixel readout process in which the controller reads a first voltage based upon charge stored on the floating diffusion capacitor and charge stored on the dual conversion gate capacitor, and reads a second voltage based upon charge stored on the storage diode.

3. The time-of-flight camera of claim 2, wherein instructions are executable to measure the first voltage by operating a dual conversion gate transistor between the dual conversion gate capacitor and the floating diffusion capacitor, and then read the first voltage.

4. The time-of-flight camera of claim 2, wherein the instructions are executable to operating a reset gate transistor to drain the charge stored on the floating diffusion capacitor and charge stored on the dual conversion gate capacitor before reading the second voltage.

5. The time of flight camera of claim 4, wherein the instructions are executable to control a transfer gate transistor to transfer charge to the floating diffusion capacitor to read the second voltage.

6. The time-of-flight camera of claim 1, wherein the pixel comprises one or more of a photodiode and a photogate.

7. The time-of-flight camera of claim 1, wherein the storage diode comprises a pinned diode.

8. The time of flight camera of claim 1, further comprising a passivation layer between the storage diode and a front side of the image sensor.

9. The time of flight camera of claim 1, further comprising an isolation layer between the storage diode and a bulk semiconductor portion of the image sensor.

10. A time-of-flight camera, comprising:
a global shutter image sensor comprising a plurality of pixels, each pixel of the plurality of pixels comprising
a drain gate; and
two or more taps, each tap comprising
a photogate;
a storage diode configured to receive charge from the photogate during the integration period,
a floating diffusion capacitor configured to receive charge overflow from the storage diode during the integration period, and
a dual conversion gate capacitor configured to receive charge overflow from the floating diffusion capacitor during the integration period; and
a controller comprising instructions executable to control each pixel during the integration period and also during a readout period in which the controller reads a first voltage based upon charge stored on the floating diffusion capacitor and charge stored on the dual conversion gate capacitor, and reads a second voltage based upon charge stored on the storage diode.

11. The time-of-flight camera of claim 10, wherein the storage diode comprises a pinned diode.

12. The time-of-flight camera of claim 10, wherein instructions are executable to measure the first voltage by operating a dual conversion gate transistor between the dual conversion gate capacitor and the floating diffusion capacitor, and then reading the first voltage.

13. The time-of-flight camera of claim 10, wherein the instructions are executable to operating a reset gate transistor to drain the charge stored on the floating diffusion capacitor and charge stored on the dual conversion gate capacitor before reading the second voltage.

14. The time of flight camera of claim 13, wherein the instructions are executable to control a transfer gate transistor to transfer charge to the floating diffusion capacitor to read the second voltage.

15. The time of flight camera of claim 10, further comprising a passivation layer between the storage diode and a front side of the image sensor.

16. The time of flight camera of claim 10, further comprising an isolation layer between the storage diode and a bulk semiconductor portion of the image sensor.

17. A method of operating a time of flight image camera comprising an image sensor, the method comprising:
integrating a plurality of pixels via a global shutter during an integration period;
for each of one or more pixel taps of the image sensor, during the integration period,
storing integrated charge at a storage diode, the storage diode comprising a pinned diode,
storing charge overflow from the storage diode at a floating diffusion capacitor, and
storing charge overflow from the floating diffusion capacitor at a dual conversion gate capacitor;
during a readout period, for the pixel tap, reading a first voltage across the floating diffusion capacitor and the dual conversion gate capacitor, the first voltage based on a first portion of charge from the integration period, the first portion of charge comprising charge overflow stored on the floating diffusion capacitor and the dual conversion gate capacitor;
draining the first portion of charge via a reset gate transistor; and
reading a second voltage across the floating diffusion capacitor based upon a second portion of charge from the integration period, the second portion of charge stored on the storage diode.

18. The method of claim 17, wherein the one or more pixel taps comprises a first set of pixels having a higher incident light intensity during the integration period, and the method further comprising, for each pixel tap of one or more pixel taps of a second set of pixel taps having a lower incident light intensity during the integration period,
storing charge from the integration period on the storage diode and not on the floating diffusion capacitor or the dual conversion gate capacitor.

19. The method of claim 17, further comprising measuring the first voltage by opening a dual conversion gate transistor between the dual conversion gate capacitor and the floating diffusion capacitor to connect the dual conversion gate capacitor and the floating diffusion capacitor in parallel, and then reading the first voltage.

20. The method of claim 17, further comprising, after draining the first portion of charge, reading the second voltage by closing the dual conversion gate transistor, and then opening a transfer gate to transfer charge from the storage diode to the floating diffusion capacitor.
